(19) United States
(12) Patent Application Publication
(10) Pub. No.: US 2026/0114235 A1
(43) Pub. Date: Apr. 23, 2026

(54) THERMAL-PROCESS APPARATUSES WITH CURVED SUBSTRATE-FACING SURFACES

(71) Applicant: CANON KABUSHIKI KAISHA, Tokyo (JP)

(72) Inventors: Seth J. Bamesberger, Austin, TX (US); Byung-Jin Choi, Austin, TX (US)

(21) Appl. No.: 18/923,455

(22) Filed: Oct. 22, 2024

(51) Int. Cl. H01L 21/687; G03F 7/00

(52) U.S. Cl. CPC H10P 72/7612; G03F 7/0002

(57) ABSTRACT

Some embodiments of a support system comprise a thermal source; a curved structure, wherein the curved structure has a curved supporting surface and a flat bottom surface, wherein the flat bottom surface faces a surface of the thermal source; and a retaining plate including a first surface that rests on the surface of the thermal source, a second surface opposite to the first surface, and a retaining feature, wherein the curved structure is positioned in the retaining feature and at least part of the curved supporting surface extends above the second surface of the retaining plate, and wherein the retaining feature has surface that limits movement of the curved structure away from the thermal source.

### BACKGROUND

Technical Field: This application generally concerns a thermal-process chamber that may be used in combination with semiconductor processing tools, such as imprint lithography tools and inkjet-based adaptive planarization tools.

Background: Many processes that are performed in semiconductor processing subject a semiconductor wafer or other such substrate to very high temperatures (e.g., high-temperature treatments, high-temperature processes). Heating to a high temperature is used in various processes to trigger physical reactions (e.g., chemical reactions) to improve the physical, optical, electrical, or chemical properties of the wafer in order to enhance the performance or quality of a resulting integrated circuit or semiconductor device, for example.

High-temperature processing may be required after or during processes for patterning, plasma etching, coating, cleaning, ion implantation, or the like. In a typical processing procedure, a wafer is transferred from a room temperature storage device by a robotic wafer handler into a processing or reaction chamber, where it is subjected to a high-temperature treatment or processing and is then transferred by the wafer handler from the high-temperature chamber to a chamber for cooling the wafer, or back to the same storage device or to a separate storage device for processed wafers. The chamber for cooling the wafer cools the wafer to a specified temperature.

### SUMMARY

Some embodiments of a support system comprise a thermal source; a curved structure, wherein the curved structure has a curved supporting surface and a flat bottom surface, wherein the flat bottom surface faces a surface of the thermal source; and a retaining plate including a first surface that rests on the surface of the thermal source, a second surface opposite to the first surface, and a retaining feature. The curved structure is positioned in the retaining feature and at least part of the curved supporting surface extends above the second surface of the retaining plate. And the retaining feature has a surface that limits movement of the curved structure away from the thermal source.

Some embodiments of a support system comprise a thermal source having a planar surface; a first curved structure, wherein the first curved structure has a curved surface and a flat bottom surface, wherein the flat bottom surface is proximal to the thermal source; and a retaining plate including a first surface that rests on the planar surface of the thermal source, a second surface opposite to the first surface, and a first retaining feature. A distance between the planar surface of the thermal source and a part of the curved surface that is farthest from the planar surface of the thermal source is greater than a distance between the second surface of the retaining plate and the planar surface of the thermal source. And the first retaining feature has a curved or chamfered surface that limits movement of the first curved structure away from the planar surface of the thermal source.

Some embodiments of a support system comprise a thermal source having a planar surface; a curved structure, wherein the curved structure has a curved surface and a flat bottom surface, wherein the flat bottom surface is proximal to the planar surface of the thermal source; and a retaining plate including a first surface that rests on the planar surface of the thermal source, a second surface opposite to the first surface, and a first retaining feature. A distance between the planar surface of the thermal source and a part of the curved surface that is farthest from the planar surface of the thermal source is greater than a distance between the second surface of the retaining plate and the planar surface of the thermal source.

Some embodiments of a method comprise supporting a substrate on a support system. The support system comprises a thermal source; a curved structure, wherein the curved structure has a curved supporting surface and a flat bottom surface, wherein the flat bottom surface faces a surface of the thermal source; and a retaining plate including a first surface that rests on the surface of the thermal source, a second surface opposite to the first surface, and a retaining feature, wherein the curved structure is positioned in the retaining feature and at least part of the curved supporting surface extends above the second surface of the retaining plate, and wherein the retaining feature has a surface that limits movement of the curved structure away from the thermal source.

### BRIEF DESCRIPTION OF THE DRAWINGS

FIG. 1A is a schematic illustration of an example embodiment of a substrate-processing system.

FIG. 1B illustrates an example embodiment of a thermal-process chamber in an open position.

FIG. 2 illustrates an example embodiment of an upper member.

FIG. 3 illustrates sectional views of the upper member and the lower member when the thermal-process chamber is in an open position.

FIG. 4 illustrates sectional views of the upper member and the lower member when the thermal-process chamber is in a closed position.

FIG. 5 illustrates an exploded sectional view of a thermal source, a retaining plate, and curved structures.

FIG. 6A illustrates an example embodiment of an inner curved structure.

FIG. 6B illustrates an example embodiment of an outer curved structure.

FIG. 7A illustrates an example embodiment of outer curved structures, a retaining plate, and a substrate.

FIG. 7B illustrate an example embodiment of an inner curved structure, an outer curved structure, a retaining plate, and a substrate.

FIG. 8A illustrates an example embodiment of a retaining feature.

FIG. 8B illustrates an example embodiment of a retaining feature.

FIG. 8C illustrates an example embodiment of a retaining feature.

FIG. 9A illustrates an example embodiment of a curved structure.

FIG. 9B illustrates an example embodiment of a curved structure.

FIG. 9C illustrates an example embodiment of a curved structure.

FIG. 9D illustrates an example embodiment of a curved structure.

### DESCRIPTION

The following paragraphs describe certain explanatory embodiments. Other embodiments may include alternatives, equivalents, and modifications. Additionally, the explanatory embodiments may include several novel features, and a particular feature may not be essential to some embodiments of the devices, systems, and methods that are described herein. Furthermore, some embodiments include features from two or more of the following explanatory embodiments. Thus, features from various embodiments may be combined and substituted as appropriate.

Also, as used herein, the conjunction “or” generally refers to an inclusive “or,” although “or” may refer to an exclusive “or” if expressly indicated or if the context indicates that the “or” must be an exclusive “or.”

Moreover, as used herein, the terms “first,” “second,” “third,” and so on, do not necessarily denote any ordinal, sequential, or priority relation and may be used to more clearly distinguish one member, operation, element, group, collection, set, region, section, etc. from another without expressing any ordinal, sequential, or priority relation. Thus, a first member, operation, element, group, collection, set, region, section, etc. discussed below could be termed a second member, operation, element, group, collection, set, region, section, etc. without departing from the teachings herein.

And in the following description and in the drawings, like reference numbers designate identical or corresponding members throughout the several views.

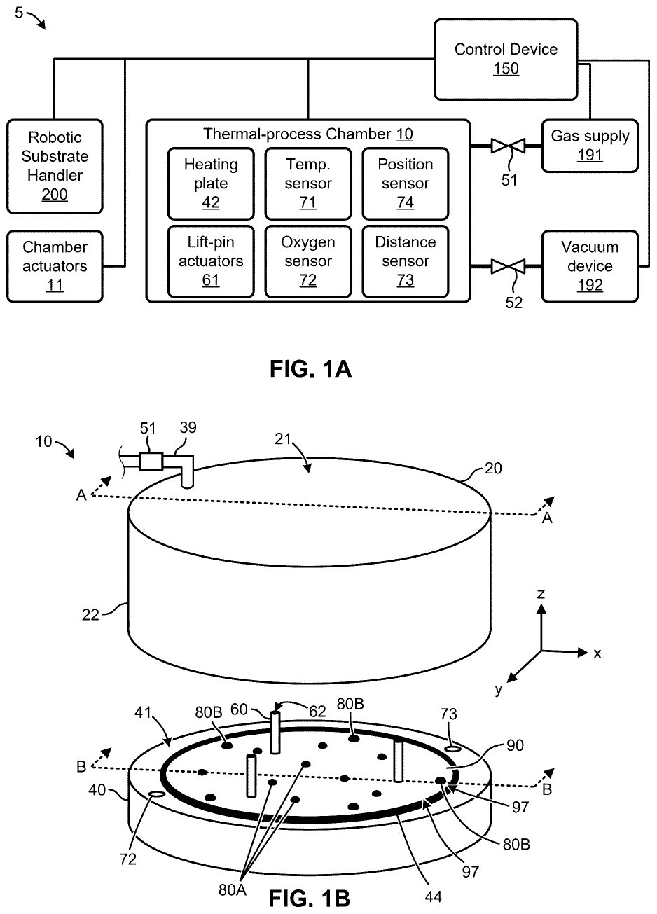

FIG. 1A is a schematic illustration of an example embodiment of a substrate-processing system 5. The substrate-processing system 5 includes a thermal-process chamber 10, chamber actuators 11, a control device 150, a robotic substrate handler 200, a gas supply 191, a vacuum device 192, a supply-side valve 51, and an exhaust-side valve 52.

The thermal-process chamber 10 (chamber 10) performs thermal processes (e.g., baking, cooling) on substrates 300 (e.g., wafers). The thermal-process chamber 10 may be a baking machine, may be a cooling machine, or may be a thermal module of a baking machine or a thermal module of a cooling machine, for example a combined baking-cooling machine. And a baking machine, a cooling machine, or a thermal module may include one or more of the following in addition to the thermal-process chamber 10: the control device 150, the chamber actuators 11, the robotic substrate handler 200, the gas supply 191, the vacuum device 192, the supply-side valve 51, and the exhaust-side valve 52.

The chamber actuators 11 can open and close the thermal-process chamber 10. The robotic substrate handler 200 can place a substrate in the thermal-process chamber 10 or remove a substrate from the thermal-process chamber 10. The gas supply 191 can supply a purge gas to the thermal-process chamber 10. And the vacuum device 192 can remove gases from the thermal-process chamber 10 (e.g., by generating a negative pressure that draws gases from the thermal-process chamber 10).

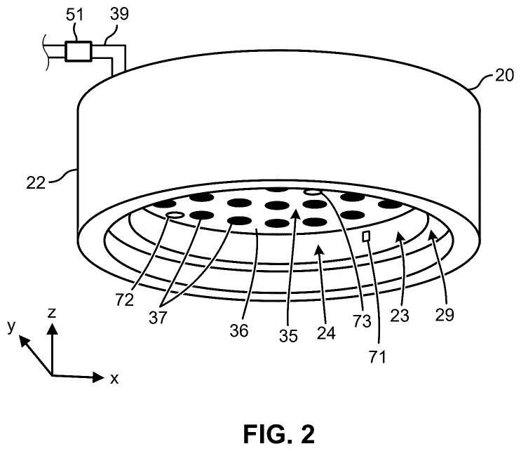

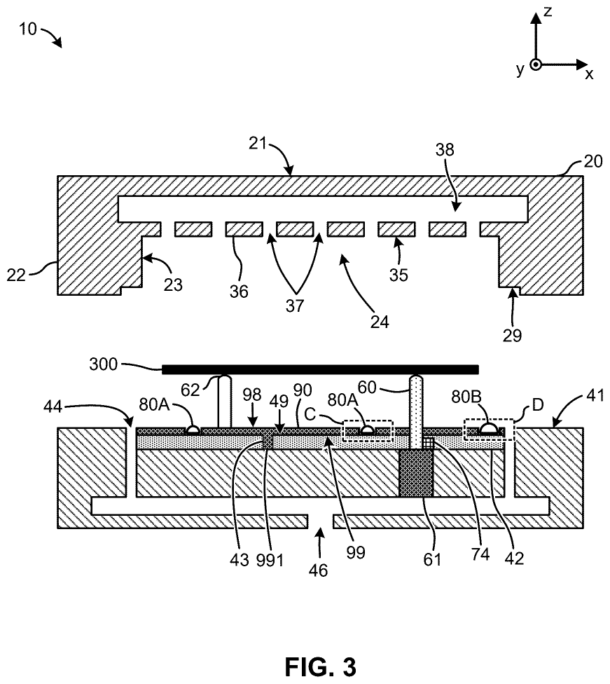

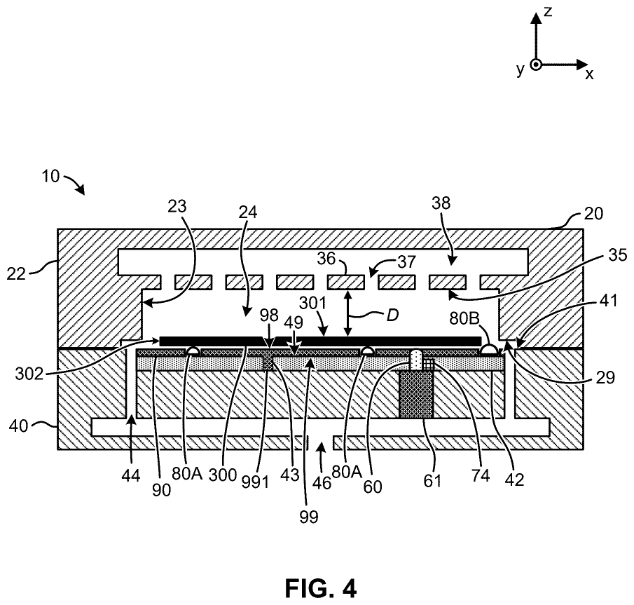

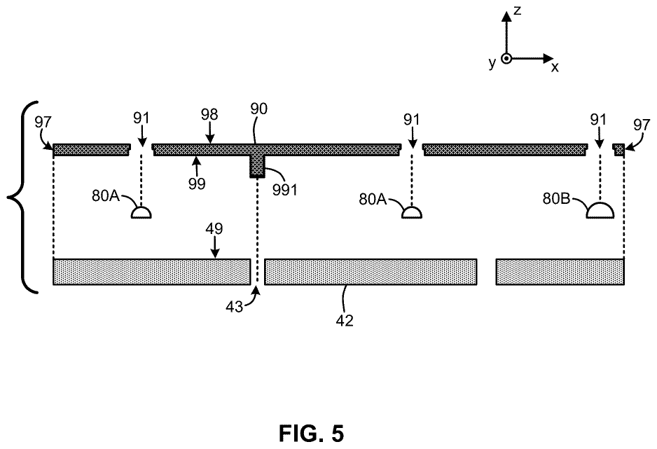

FIG. 1B illustrates an example embodiment of a thermal-process chamber 10 (chamber 10) in an open position. The chamber 10 includes an upper member 20 (a chamber lid) and a lower member 40 (a chamber base). FIG. 2 illustrates an example embodiment of the upper member 20. Also, FIG. 3 illustrates sectional views of the upper member 20 and the lower member 40 when the thermal-process chamber 10 is in an open position. And FIG. 4 illustrates sectional views of the upper member 20 and the lower member 40 when the thermal-process chamber 10 is in a closed position. FIG. 5 illustrates an exploded sectional view of a thermal source 42, a retaining plate 90, and curved structures 80.

In FIG. 1B, the view of the chamber 10 is a perspective view. The view in FIG. 2 is a perspective view of the upper member 20 that looks upward along the z axis, showing the interior of the upper member 20. And the sectional views of the upper member 20 that are shown herein, including the sectional views in FIGS. 3 and 4, are taken along the plane that is indicated by the line A-A in FIG. 1B, and the sectional views of the lower member 40 that are shown herein, including the sectional views in FIGS. 3 and 4, are taken along the plane that is indicated by the line B-B in FIG. 1B. Also, for illustrative purposes, FIGS. 3 and 4 show one lift pin 60 that does not lie in the plane that is indicated by the line B-B in FIG. 1B. And the sectional view in FIG. 5 is taken along the plane that is indicated by the line B-B in FIG. 1B.

The chamber actuators 11 can move one or more of the upper member 20 and the lower member 40 along the z-axis, and therefore can open and close the chamber 10.

The chamber 10 can perform one or more thermal processes on a substrate (e.g., wafer) while the substrate is in the chamber 10. Examples of thermal processes include baking processes (or other high-temperature processes) and cooling processes (e.g., annealing processes), which may be performed in controlled atmospheres.

The upper member 20 (the chamber lid) includes one or more walls 22, a recessed region 24 (also referred to as a recessed portion), one or more plateaus 29 that surround the recessed region 24, a chamber ceiling 35, a gas-flow distributor 36 (distributor 36), a distribution chamber 38, and an inlet port 39. The recessed region 24 is three-dimensional space that is defined by the chamber ceiling 35 and by one or more chamber sidewalls 23 (inner surfaces). Also, some embodiments do not include the plateau 29.

The one or more walls 22 extend downward from the periphery of the upper surface 21 of the upper member 20. For example, if the shape of the upper member 20 on the x-y plane is a circle or an oval (e.g., as shown in FIGS. 1B and 2), then the upper member 20 may have one wall 22 that circumscribes the outer edge of the upper surface 21. Also for example, if the shape of the upper member 20 on the x-y plane is a quadrilateral, then the upper member 20 may have four walls 22 that collectively circumscribe the outer edge of the upper surface 21. A wall 22 of the upper member 20 may also be referred to herein as an “upper wall 22.” The shape of the recessed region 24 in the x-y plane, which is defined by the one or more chamber sidewalls 23, matches the shape of the substrate 300.

The inlet port 39 can receive a flow of a gas (e.g., a purge gas) from the gas supply 191. The gas-flow distributor 36 (e.g., shower head, gas distribution plate, diffusion board, discharge nozzle, perforated diffusion plate) is located in the chamber ceiling 35 in this embodiment. And, in this embodiment, the distributor 36 includes a plurality of openings 37. Gas that flows through the inlet port 39 enters the distribution chamber 38 and flows through the openings 37 of the distributor 36 into the recessed region 24. The distributor 36 may cause the gas to uniformly flow to the different areas (e.g., a central area, an area that is closer to the chamber sidewall 23) of the recessed region 24. Also, the flow of the gas into the upper member 20 can be controlled (e.g., stopped, started) by a supply-side valve 51.

The lower member 40 includes a floor 41, a thermal source 42, at least one vent 44, a gas outlet 46, lift pins 60, lift-pin actuators 61, curved structures 80, and a retaining plate 90. The curved structures 80 include both inner curved structures 80A and outer curved structures 80B. And the curved structures 80 are each positioned in a respective retaining feature 91 of the retaining plate 90. In the x-y plane, each curved structure 80 may be surrounded by the retaining plate 90.

In embodiments in which the thermal source 42 is a heating source (e.g., a heating plate), the thermal source 42 emits heat when activated, and, to heat the interior of the chamber 10, the thermal source 42 can be controlled to heat to a specific temperature based on a temperature sensor attached to the thermal source 42. In embodiments in which the thermal source 42 is a cooling source (e.g., a cooling plate), such as thermoelectric cooler, when the thermal source 42 is activated, the thermal source 42 transfers heat away from the interior of the chamber 10, and, to cool the interior of the chamber 10, the thermal source 42 can be controlled to cool the interior of the chamber 10 to a specific temperature based on a temperature sensor attached to the thermal source 42. In some embodiments, the thermal source 42 is controlled according to a detected temperature of one or more of the following: the thermal source 42, the interior of the chamber 10 (e.g., the recessed portion 24), the substrate 300, and a processing surface 301 of the substrate 300.

The retaining plate 90 rests on the thermal source 42. A first surface 99 of the retaining plate 90 faces, and rests on, a planar surface 49 of the thermal source 42. A second surface 98 of the retaining plate 90 is opposite to the first surface 99 and faces away from the thermal source 42. And the retaining plate 90 may include one or more protrusions 991 (e.g., alignment pins) that are received by corresponding openings 43 in the thermal source 42. The thermal source 42 may also include one or more protrusions (e.g., alignment pins) that are received by corresponding openings in the retaining plate 90. The one or more protrusions 991 may align the retaining plate 90 to the thermal source 42 without restricting the movement of the retaining plate 90 along the z-axis relative to the thermal source 42. And the one or more protrusions 991 and the corresponding openings 43 may be sized to allow some movement of the retaining plate 90 relative to the thermal source 42 in the x-y plane. Other than the one or more protrusions 991, the retaining plate 90 is preferably not be affixed or attached to the thermal source 42. Allowing some movement of the retaining plate 90 relative to the thermal source 42 in the x-y plane may be advantageous because of the difference between the coefficient of thermal expansion of the retaining plate 90 and the coefficient of thermal expansion of the thermal source 42.

The at least one vent 44 can be an annular opening adjacent to the thermal source 42 that has an annular connection to an annular vacuum chamber that supplies a uniform pressure drop around the thermal source 42. The vent 44 may be an opening in the floor 41 adjacent the thermal source 42, and the vent 44 allows gases to travel through the floor 41. In some embodiments, the thermal source 42 also includes one or more vents 44 therethrough. Gas that flows into the at least one vent 44 exits through the gas outlet 46, which can be connected to the vacuum device 192. Also, for example, the gas outlet 46 may be attached to the exhaust-side valve 52. Additionally, the vacuum device 192 may be a vacuum chamber, a fan, a region that has less pressure than the thermal-process chamber 10, or another device that can draw gas into the at least one vent 44.

The upper member 20 can be separated from the lower member 40 (e.g., by raising the upper member 20, by lowering the lower member 40), which allows a substrate 300 to be placed on the support surfaces 62 of the lift pins 60 or removed from the support surfaces 62 of the lift pins 60. Furthermore, as shown in FIGS. 3 and 4, the support surfaces 62 may be curved (e.g., hemispherical, convex).

Also, the chamber 10 may include one or more sensors. Examples of sensors include the following: temperature sensors 71, oxygen sensors 72, distance sensors 73, and position sensors 74. For example, distance sensors 73 may detect the distance between the chamber ceiling 35 and the substrate 300 or the distance between the upper member 20 and the lower member 40. Also for example, position sensors 74 may detect the positions of the lift pins 60. And the sensors (e.g., temperature sensors 71, oxygen sensors 72, distance sensors 73, and position sensors 74) communicate with (e.g., send information to) the control device 150.

The control device 150 controls the thermal source 42 and the lift-pin actuators 61. Also, the control device 150 receives information (e.g., sensor measurements) from the sensors (e.g., temperature sensors 71, oxygen sensors 72, distance sensors 73, and position sensors 74).

As shown in FIG. 4, when the thermal-process chamber 10 is in a closed position, the wall 22 (or walls 22) of the upper member 20 are in contact with, or close to, the floor 41 of the lower member 40. At least part of the substrate 300 is positioned within the recessed region 24. And there is a gap of distance D between the chamber ceiling 35 of the upper member 20 and the substrate 300. Also, the lift pins 60 have been lowered such that the substrate 300 rests on the inner curved structures 80A.

During the overall processing of the substrate 300 (e.g., before the substrate 300 is placed in the chamber 10), a processing surface 301 (proximal surface, top surface) of the substrate 300, which is proximal to the chamber ceiling 35, may be subjected to one or more processes, such as patterning, plasma etching, coating, cleaning, curing, oxidation, layer formation, deposition, doping, planarization, etching, formable-material removal, and ion implantation.

And during the processing of the substrate 300 by the chamber 10, the chamber 10 heats or cools the substrate 300 (e.g., the processing surface 301) to a specified temperature for a specified duration. Once the duration ends, the chamber 10 opens. And the substrate 300 can be removed from the open chamber 10, for example by the robotic substrate handler 200.

The lift pins 60 can hold a substrate 300. In this embodiment, the lower member 40 includes a respective lift-pin actuator 61 for each of the lift pins 60, and each lift-pin actuator 61 can raise and lower a respective lift pin 60. In some embodiments, a lift-pin actuator 61 can raise or lower two or more lift pins 60. By raising or lowering the lift pins 60, the lift-pin actuators 61 can cause the lifts pins 60 to raise or lower a substrate 300 that is held by the lift pins 60. Accordingly, the lifts pins 60 and the lift-pin actuators 61 can operate together to raise or lower the substrate 300 that is held by the lift pins 60. And the lift pins 60 can lower a substrate 300 until the substrate 300 rests on the inner curved structures 80A.

The curved structures 80 may reduce the chipping that can occur when the substrate 300 contacts the curved structures 80. For example, the inner curved structures 80A may reduce the chipping that can occur when the substrate 300 moves (e.g., due to local gas flow conditions, during thermal expansion, or during thermal contraction) while the substrate 300 rests on the inner curved structures 80A. In systems in which the back side of the substrate 300 (the side that faces the thermal source 42) rests on flat supports (e.g., the flat surfaces of cylindrical-shaped pins) instead of curved structures 80, the back side of the substrate 300 may be subjected to 10-30 micron chipping. The curved structures 80 may reduce this chipping. Also, in embodiments in which the chamber 10 is a baking chamber, the heat in the chamber 10 may prevent the use of soft and flexible materials.

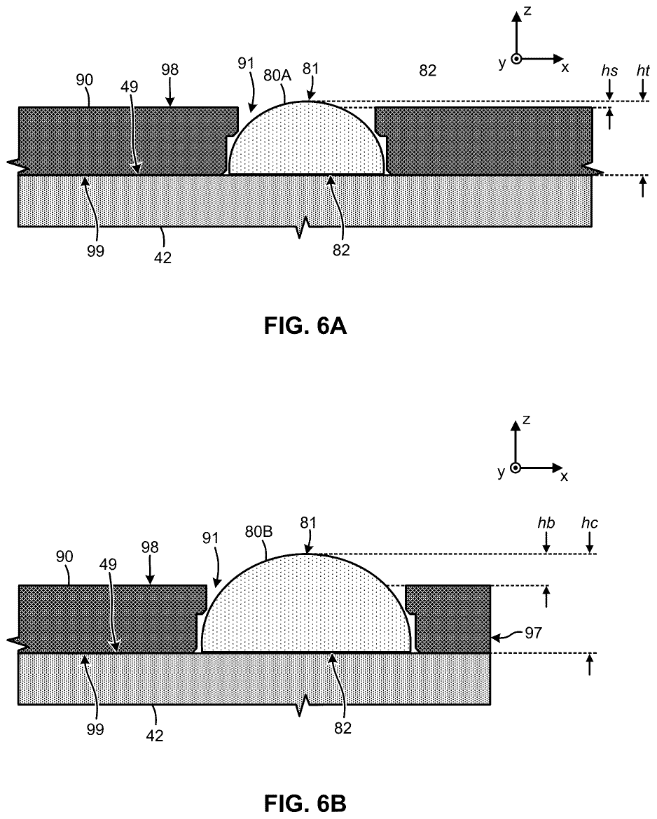

FIGS. 6A and 6B illustrate example embodiments of curved structures 80.

FIG. 6A illustrates an example embodiment of an inner curved structure 80A. FIG. 6A is an enlarged view of region C in FIG. 3, and accordingly FIG. 6A is a sectional view, taken along the plane that is indicated by the line B-B in FIG. 1B, of the inner curved structure 80A, the thermal source 42, and the retaining plate 90. FIG. 6B illustrates an example embodiment of an outer curved structure 80B. FIG. 6B is an enlarged view of region D in FIG. 3, and accordingly FIG. 6B is a sectional view, taken along the plane that is indicated by the line B-B in FIG. 1B, of the outer curved structure 80B, the thermal source 42, and the retaining plate 90.

The curved structures 80 in FIG. 6A-B are each positioned in a respective retaining feature 91 of the retaining plate 90. And the curved structures 80 in FIG. 6A- B each include a respective curved surface 81 and a respective flat bottom surface 82. The flat bottom surfaces 82 face, and rest on, the thermal source 42. At least some portions of the curved surfaces 81 face away from the thermal source 42, and thus the curved surfaces 81 may be described as facing away from the thermal source 42. When a substrate 300 rests on the lift pins 60 or on some of the curved structures 80, portions of the curved surfaces 81 face the substrate 300. Thus, the curved surfaces 81 may also be referred to as curved substrate-facing surfaces 81. Also, the curved surface 81 of an inner curved structure 80A may be referred to as a curved supporting surface 81, and the curved surface 81 of an outer curved structure 80B may be referred to as a curved contact surface 81.

A curved surface 81 is configured to contact a substrate 300. The curved surface 81 (curved supporting surface 81) of an inner curved structure 80A is configured to contact and support a substrate 300. Also, although a substrate 300 that is aligned to (e.g., centered on) the thermal source 42 or the retaining plate 90 may not contact any of the outer curved structures 80B, when there is contact between an outer curved structure 80B and a substrate 300, the curved surface 81 (curved contact surface 81) of the outer curved structure 80B is configured to contact the outer edge 302 of the substrate 300. At least some of each curved surface 81 extends above the second surface 98 of the retaining plate 90.

A curved surface 81 may have a convex shape. And the curvature of a curved surface 81 may be symmetrical in the x-z and y-z planes (e.g., the curved surface 81 may have the shape of a spherical cap (spherical dome) of a sphere (e.g., a hemispherical shape), and the curvature of a curved surface 81 may not be symmetrical in the x-z and y-z planes (e.g., the curved surface 81 may have the shape of a spherical cap of a spheroid or an ellipsoidal cap of an ellipsoid). A spherical cap (spherical dome) of a sphere or spheroid is the portion of the sphere or spheroid cut off by a plane. An ellipsoidal cap (ellipsoidal dome) is the portion of the ellipsoid cut off by a plane. The curved surface 81 has a curvature that bulges towards the substrate 300 that is being supported, ensuring that there are no sharp edges that are in contact with the substrate 300 such that when the substrate 300 expands or contracts while resting on, or while otherwise contacting, the curved surface 81, there is a minimal chance of chipping or scratching due to the curved surface 81. The curved surface 81 can be symmetric about the z axis. In an alternative embodiment, the curved surface 81 is not symmetric about the z axis but does have curvature in the z-axis direction. Furthermore, for example, the curved surface 81 may be curved in only one of the x-z plane and the y-z plane, such as the shape of horizontal cylindrical segment, which has the shape of a cylinder that has been cut by a plane that is perpendicular to the base of the cylinder.

The curvature of the curved surfaces 81 may reduce chipping of the parts of the substrate 300 that contact the curved surfaces 81.

Also, the surface roughness of a curved surface 81 or a flat bottom surface 82 may be very low (i.e., a curved surface 81 and a flat bottom surface 82 may be very smooth). For example, the surface roughness may be equal to or less than 0.4 Ra (micrometers), equal to or less than 0.3 Ra, equal to or less than 0.2 Ra, or equal to or less than 0.1 Ra. The surface roughness may, for example, be calculated using an ISO 10110-8 average roughness method for optical elements. The curved surface 81 may have an optically polished surface (polished to a degree suitable for an optical component). The curved surface 81 can have a non-optical surface that has a roughness that is equivalent to an optically polished surface. And the curved structures 80 may be composed of one or more materials that can be sufficiently smoothed. In some embodiments, the curved structures 80 are composed of one or more of the following materials: ceramic (e.g., sapphire, quartz), vitreous-enamel-coated structures, glass (e.g., fused silica, optical glass), and plastic (e.g., acrylic, optical plastic). The one or more materials that compose a curved structure 80 can be materials that are softer than the substrate 300 over the temperature range that the substrate 300 experiences in the thermal-process chamber 10. This may further reduce chipping or scratching of the substrate 300 that is caused by contact with the curved structure 80.

And the one or more materials that compose a curved structure 80 can be materials that can withstand the temperatures in the chamber 10. For example, if the chamber 10 is a baking chamber, then the one or more materials that compose a curved structure 80 can be selected to withstand the heat in the baking chamber without a significant change in shape (e.g., without melting) and without a significant change in their relevant material properties. For example, a material of the curved structure 80 should not generate significant (e.g., on the order of ppb) volatile compounds (for example organic compounds or metal ions) when exposed to the operating temperature of the chamber 10. The material of the curved structure 80 will be exposed to the operating temperature for long periods of time, and the material of the curved structure 80 should have a high continuous-use temperature that is greater than the operating temperature.

The flat bottom surface 82 is configured to rest on a surface, such as the planar surface 49 of the thermal source 42. The flat bottom surface 82 limits (e.g., prevents) rotation of the curved structure 80 around the x axis and the y axis. If a curved structure 80 rolls, then the curved structure 80 could carry particles, such as metal ions, from the planar surface 49 of the thermal source 42 to the part of the curved structure 80 that contacts the substrate 300, which could damage or contaminate the substrate 300.

In FIG. 6A, which illustrates the inner curved structure 80A, the height of the part of the curved supporting surface 81 that is most distant from the plane of the second surface 98 of the retaining plate 90 (which is also the part of the curved supporting surface 81 that is most distant from the planar surface 49 of the thermal source 42) is height hs. Accordingly, height hs indicates the distance between the plane of the second surface 98 and the part of the curved supporting surface 81 of the inner curved structure 80A that is most distant from the plane of the second surface 98. The curved supporting surface 81 may be sized such that height hs has a specified value or is within a specified range (for example 20-800 μm). Furthermore, because at least some of the curved supporting surface 81 extends above the second surface 98, a substrate 300 that rests on the curved supporting surface 81 does not contact the retaining plate 90. Also, relative to the planar surface 49 of the thermal source 42, the height of the part of the curved supporting surface 81 that is most distant from the planar surface 49 of the thermal source 42 is height ht in FIG. 6A. Accordingly, height ht indicates the distance between the planar surface 49 of the thermal source 42 and the part of the curved supporting surface 81 that is most distant from the thermal source 42, and height ht also indicates the shortest distance between the planar surface 49 of the thermal source 42 and the part of the curved supporting surface 81 that is most distant from the planar surface 49 of the thermal source 42.

In FIG. 6B, which illustrates the outer curved structure 80B, the height of the part of the curved contact surface 81 that is most distant from the plane of the second surface 98 is height hb. Accordingly, height hb indicates the distance between the plane of the second surface 98 and the part of the curved contact surface 81 that is most distant from the plane of the second surface 98. The curved contact surface 81 may be sized such that height hb has a specified value or is within a specified range. Furthermore, height hb is greater than height hs. The height hb can be selected based on the thickness variation of the substrate 300. Also, relative to the planar surface 49 of the thermal source 42, the height of the part of the curved contact surface 81 that is most distant from the planar surface 49 of the thermal source 42 is height hc in FIG. 6B. Accordingly, height hc indicates the distance between the planar surface 49 of the thermal source 42 and the part of the curved contact surface 81 that is most distant from the planar surface 49 of the thermal source 42, and height hc also indicates the shortest distance between the planar surface 49 of the thermal source 42 and the part of the curved contact surface 81 that is most distant from the planar surface 49 of the thermal source 42. And height hc is greater than height ht.

In some embodiments, the outer curved structure 80B has a cylindrical shape and is secured not by the retaining plate 90, but by other means. The outer curved structure 80B can also have a cylindrical shape with chamfered edges.

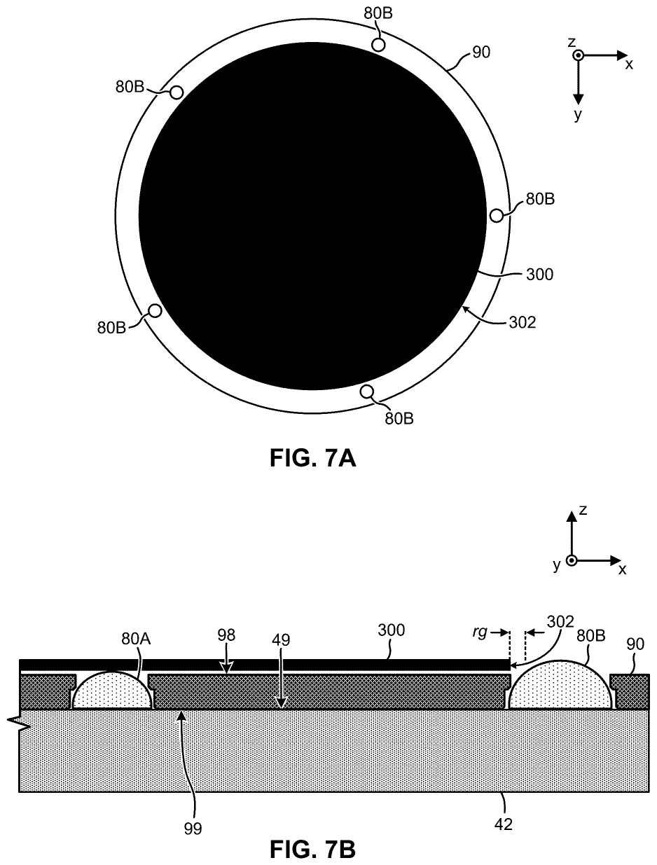

The outer curved structures 80B are arranged around the periphery of the retaining plate 90 such that a substrate 300 can rest on the inner curved structures 80A without contacting any of the outer curved structures 80B. For example, FIG. 7A illustrates an example embodiment of outer curved structures 80B, a retaining plate 90, and a substrate 300. The substrate 300 is centered relative to the retaining plate 90, and the substrate 300 rests on inner curved structures 80A, which are therefore not visible in FIG. 7A. The substrate 300 does not contact any of the outer curved structures 80B while the substrate 300 is centered on the retaining plate 90.

When a substrate 300 is resting on the inner curved structures 80A (e.g., as shown in FIG. 4), the curved contact surfaces 81 of the outer curved structures 80B limit the movement of the substrate 300 in the x-y plane. The substrate 300 can move a small amount in the x-y plane, but, if a substrate 300 moves enough in any direction in the x-y plane, the substrate 300 will contact at least one curved contact surface 81 that will stop further movement in that direction. For example, FIG. 7B illustrates an example embodiment of an inner curved structure 80A, an outer curved structure 80B, a retaining plate 90, and a substrate 300. The substrate 300 is resting on the inner curved structure 80A. In this embodiment, the retaining plate 90 and the outer curved structure 80B are adapted such that, when the substrate 300 is centered on the retaining plate 90, there is a radial gap rg between the radial edge 302 of the substrate 300 and the closest contact point on the curved contact surface 81 of the outer curved structure 80B. Thus, in the direction of the outer curved structure 80B, the maximum distance that a centered substrate 300 can move is equal to the radial gap rg because contact with the curved contact surface 81 prevents any further movement in the direction of the outer curved structure 80B. The radial gap rg can be set based on the positioning accuracy of the robotic substrate handler 200.

As noted above, the outer curved structures 80B are arranged at a periphery of the retaining plate and, accordingly are close to the radial edge 97 of the retaining plate 90. The radial edge 97 is closer to the outer curved structures 80B than to the inner curved structures 80A. Thus, the respective distance between any outer curved structure 80B and the point on the radial edge 97 that is closest to the outer curved structure 80B is less than the respective distances between the inner curved structures 80A and the respective points on the radial edge 97 that are closest to the inner curved structures 80A. Also, the respective distances between a center of the retaining plate 90 and each of the outer curved structures 80B are each greater than the respective distances between the center of the retaining plate 90 and each of the inner curved structures 80A.

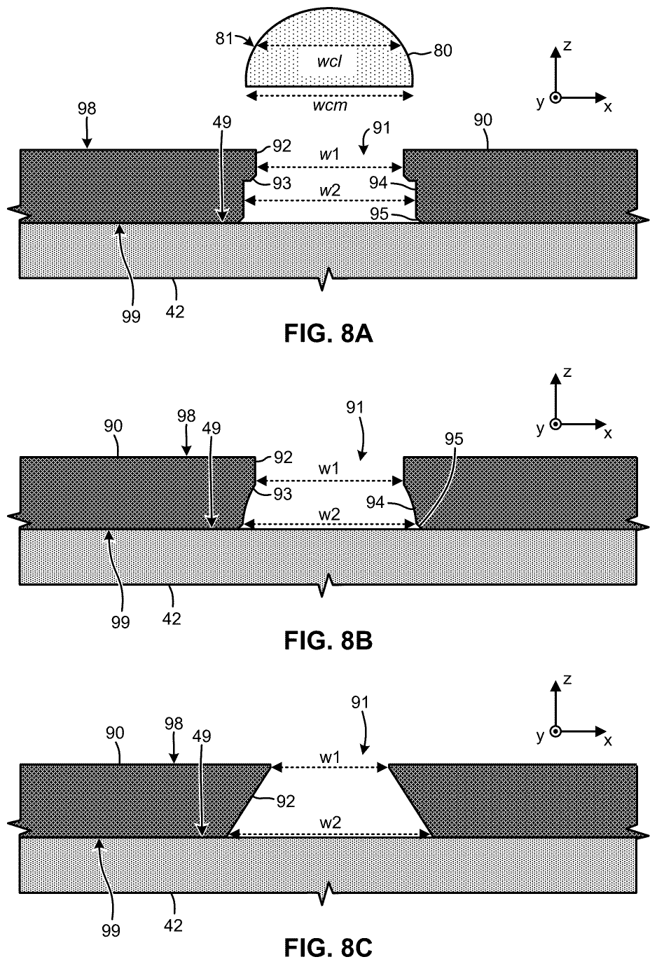

FIG. 8A illustrates an example embodiment of a retaining feature 91. The view of the retaining feature 91 is a sectional view. In FIG. 8A, the retaining feature 91 includes an opening that extends through the retaining plate 90. The retaining feature 91 includes a retaining structure 92 and a positioning structure 94. The width w1 of the opening of the retaining feature 91 in the retaining structure 92 is less than the width w2 of the opening of the retaining feature 91 in the positioning structure 94. The curved structure 80 that corresponds to the retaining feature 91 is sized so that the curved structure 80 has an overall width wcm (maximum width wcm) between width w1 and width w2. In some embodiments, the retaining feature 91 is, or includes, a through hole through the retaining plate 90 that is either a countersunk through hole or a counterbored through hole.

In some embodiments, only the retaining plate 90 limits the movement of the curved structures 80 (e.g., nothing other than gravity and the retaining plate 90 hold the curved structures 80 against the thermal source 42)—the curved structures 80 are not otherwise attached (e.g., affixed, adhered) to the thermal source 42. Thus, in some embodiments, the curved structures 80 are not directly attached to the thermal source 42.

The retaining structure 92 limits (e.g., restricts, prohibits) movement away from the thermal source 42 (which is the positive z-axis direction in FIG. 8A) by a curved structure 80 that is positioned in the retaining feature 91. The retaining structure 92 includes a retaining contact surface 93, which is chamfered in FIG. 8A, but which may also be curved or have another shape. The retaining structure 92 may be configured (e.g., sized) such that, when a curved structure 80 rests on the thermal source 42, the curved structure 80 is not in contact with the contact surface 93. This reduces contact between the curved structure 80 and the contact surface 93, which reduces the debris (e.g., particles that detach from either the curved structure or the contact surface 93) that may be produced when a curved structure 80 contacts the contact surface 93.

Contact with the contact surface 93 limits the maximum distance that a curved structure 80 can move away from the thermal source 42. In some embodiments (e.g., embodiments in which a curved structure 80 is not directly attached to the thermal source 42), a curved structure 80 can move away from the thermal source 42 (in the z-axis direction) up to the distance at which the curved structure 80 contacts the contact surface 93, but the contact with the contact surface 93 prevents the curved structure 80 from moving any farther away from the thermal source 42. For example, in some embodiments (e.g., the embodiments in FIG. 6A and FIG. 6B), when a curved structure 80 is at a maximum distance from the planar surface 49 of the thermal source 42, contact between (i) a part of the curved surface 81 that is located at an area where a width wcl (e.g., diameter in the x-y plane) of the curved structure 80 is less than a maximum width wcm of the curved structure 80 and (ii) the contact surface 93 prevents the curved structure 80 from moving farther away from the planar surface 49 of the thermal source 42.

The chamfering or curved surface of the contact surface 93 may also reduce the debris that may be produced when a curved structure 80 contacts the contact surface 93. For example, if, instead of the chamfered retaining contact surface 93 in FIG. 8A, the retaining feature 91 included a 90 degree angle where the width of the opening of the retaining feature 91 transitions between width w1 and width w2, then the relatively sharp point of the 90 degree angle could produce more debris when a curved structure 80 contacts the retaining structure 92.

The positioning structure 94 limits the movement of a curved structure 80 in the x-y plane. In some embodiments (e.g., embodiments in which a curved structure 80 is not directly attached to the thermal source 42), the positioning structure 94 allows some movement of a curved structure 80 in the x-y plane. This allows the curved structure 80 to move, within the retaining feature 91, in the x-y plane during thermal expansion and thermal contraction. The positioning structure 94 also includes a chamfered corner 95 at the end of the positioning structure 94 that is opposite to the retaining structure 92. The chamfered corner 95 may reduce the debris that may be produced when the retaining plate 90 moves relative to (e.g., rubs against) the thermal source 42, for example during thermal expansion or thermal contraction.

FIG. 8B illustrates an example embodiment of a retaining feature 91. The retaining feature 91 includes an opening that extends through the retaining plate 90. And the retaining feature 91 includes a retaining structure 92 and a positioning structure 94. The width w1 of the opening of the retaining feature 91 in the retaining structure 92 is less than the width w2 of the opening of the retaining feature 91 in the positioning structure 94. In FIG. 8B, the retaining contact surface 93 has a curved surface, and the retaining contact surface 93 and the surface of the positioning structure 94 together form a continuous surface.

FIG. 8C illustrates an example embodiment of a retaining feature 91. The retaining feature 91 includes an opening that extends through the retaining plate 90. And the retaining feature 91 includes a retaining structure 92 that also operates as a positioning structure. Thus, the retaining structure 92 limits both the movement of a curved structure 80 away from the thermal source 42 (in the z-axis direction) and the movement of the curved structure 80 in the x-y plane. The width w1 of the opening of the retaining structure 92 near the second surface 98 of the retaining plate 90 is less than the width w2 of the opening of the retaining structure 92 on the side of the retaining plate 90 that is opposite to the second surface 98. The retaining structure 92 can include a retaining surface that is substantially tangent (within 1°) of the curved surface 81 that can come into contact with the retaining surface.

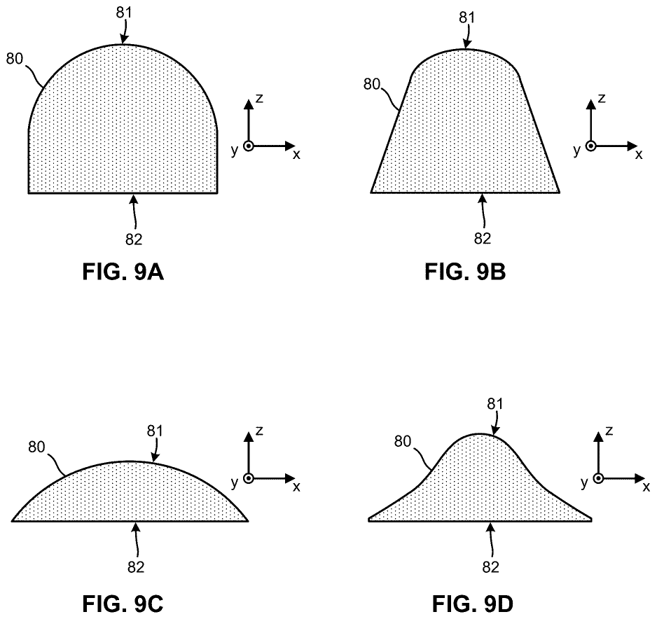

FIG. 9A illustrates an example embodiment of a curved structure 80. The view in FIG. 9A is a sectional view. In FIG. 9A, the curved structure 80 has a cylindrical shape near the flat bottom surface 82. For example, the curved structure 80 may have the shape of a spherical cap (of a sphere or a spheroid) that rests on a cylinder.

FIG. 9B illustrates an example embodiment of a curved structure 80. The view in FIG. 9B is a sectional view. In FIG. 9B, the curved structure 80 has a conical shape near the flat bottom surface 82. For example, the curved structure 80 may have the shape of a spherical or aspheric cap (of a radially symmetric convex surface such as a sphere, a spheroid, or other structure) that rests on a conical frustrum, a spherical frustrum, or a polygonal frustrum (e.g., a pentagonal frustrum, and octagonal frustrum).

FIG. 9C illustrates an example embodiment of a curved structure 80. The view in FIG. 9C is a sectional view. In FIG. 9C, the curved structure 80 has the shape of a spherical cap (of a sphere or a spheroid). For example, the shape may be the shape of a spherical cap from a sphere that was cut by a plane that intersected the sphere between the center of the sphere and the top of the sphere (i.e., the height of the spherical cap is less than the length of the radius of the sphere). Also for example, the shape may be the shape of a spherical cap from a spheroid that was cut by a plane that intersected the spheroid between the center of the spheroid and the top of the spheroid (i.e., the height of the spherical cap is less than the length of the corresponding axis (major axis or minor axis) of the spheroid).

FIG. 9D illustrates an example embodiment of a curved structure 80. The view in FIG. 9D is a sectional view. In FIG. 9D, the curved structure 80 has a curved surface 81, but the curved structure 80 is aspherical.

In the description, specific details are set forth in order to provide a thorough understanding of the embodiments disclosed. However, well-known methods, procedures, components and circuits may not have been described in detail in order to avoid unnecessarily lengthening the present disclosure.

Also, if a member (e.g., element, part, component) is referred herein as being “on,” “against,” “connected to,” or “coupled to” another member, then the member can be directly on, against, connected or coupled to the other member, but intervening members may also be present between the member and the other member. In contrast, if a member is referred to as being “directly on,” “directly against,” “directly connected to,” or “directly coupled to” another member, then there are no intervening members present between the member and the other member.

Furthermore, the terms “comprising,” “having,” “includes,” “including,” and “containing” are to be construed as open-ended terms unless otherwise noted. Accordingly, these terms, when used in the present specification, specify the presence of described features, integers, steps, operations, elements, materials, or members, but do not preclude the presence or addition of one or more other features, integers, steps, operations, elements, materials, or members that are not explicitly described.

1. A support system comprising:
a thermal source;
a curved structure, wherein the curved structure has a curved supporting surface and a flat bottom surface, wherein the flat bottom surface faces a surface of the thermal source; and
a retaining plate including a first surface that rests on the surface of the thermal source, a second surface opposite to the first surface, and a retaining feature,
wherein the curved structure is positioned in the retaining feature and at least part of the curved supporting surface extends above the second surface of the retaining plate, and
wherein the retaining feature has a surface that limits movement of the curved structure away from the thermal source.

2. The support system of claim 1, wherein the retaining feature is a through hole through the retaining plate that is one of: a countersunk through hole and a counterbored through hole; and
wherein the curved supporting surface passes through a smaller end of the through hole.

3. The support system of claim 1, wherein the support system includes a plurality of the curved structures and a corresponding plurality of the retaining features in the retaining plate.

4. The support system of claim 1, further comprising:
outer curved structures arranged at a periphery of the retaining plate,
wherein respective heights of the outer curved structures are greater than a height of the curved structure.

5. The support system of claim 1, wherein the curved supporting surface has surface roughness equal to or less than 0.3 Ra.

6. The support system of claim 1, wherein the curved supporting surface has a convex shape.

7. The support system of claim 1, wherein the curved structure can move within the limits that are due to the retaining feature.

8. The support system of claim 1, wherein the surface of the retaining feature that limits movement of the curved structure away from the thermal source is curved or chamfered.

9. A support system comprising:
a thermal source having a planar surface;
a first curved structure, wherein the first curved structure has a curved surface and a flat bottom surface, wherein the flat bottom surface is proximal to the thermal source; and
a retaining plate including a first surface that rests on the planar surface of the thermal source, a second surface opposite to the first surface, and a first retaining feature,
wherein a distance between the planar surface of the thermal source and a part of the curved surface that is farthest from the planar surface of the thermal source is greater than a distance between the second surface of the retaining plate and the planar surface of the thermal source, and
wherein the first retaining feature has a curved or chamfered surface that limits movement of the first curved structure away from the planar surface of the thermal source.

10. The support system of claim 9, wherein no part of the retaining plate is positioned between the planar surface of the thermal source and the first curved structure.

11. The support system of claim 9,
wherein the first retaining feature is a through hole through the retaining plate, and
wherein a width of the through hole near the first surface is greater than a width of the through hole near the second surface.

12. The support system of claim 9, further comprising:
a second curved structure,
wherein the second curved structure has a curved surface and a flat bottom surface, wherein the flat bottom surface faces the planar surface of the thermal source,
wherein the retaining plate further includes a second retaining feature,
wherein the second curved structure is positioned in the second retaining feature,
wherein a distance between the second retaining feature and a respective closest edge of the retaining plate is greater than a distance between the first retaining feature and a respective closest edge of the retaining plate,
wherein a distance between the planar surface of the thermal source and a part of the curved surface of the second curved structure that is farthest from the planar surface of the thermal source is less than the distance between the planar surface of the thermal source and the part of the curved surface of the first curved structure that is farthest from the planar surface of the thermal source, and
wherein the second retaining feature has a surface that limits movement of the second curved structure away from the planar surface of the thermal source.

13. The support system of claim 9, wherein the curved surface has a convex shape.

14. The support system of claim 13, wherein the convex shape is a dome.

15. The support system of claim 9, wherein, within the limits imposed by the first retaining feature, the first curved structure can move relative to the planar surface of the thermal source.

16. The support system of claim 9, wherein, within the limits imposed by the first retaining feature, when the first curved structure is at a maximum distance from the planar surface of the thermal source, contact between (i) a part of the curved surface that is located at an area where a width of the first curved structure is less than a maximum width of the first curved structure and (ii) the curved or chamfered surface of the first retaining feature prevents the first curved structure from moving farther away from the planar surface of the thermal source.

17. A support system comprising:
a thermal source having a planar surface;
a curved structure, wherein the curved structure has a curved surface and a flat bottom surface, wherein the flat bottom surface is proximal to the planar surface of the thermal source; and
a retaining plate including a first surface that rests on the planar surface of the thermal source, a second surface opposite to the first surface, and a first retaining feature,
wherein a distance between the planar surface of the thermal source and a part of the curved surface that is farthest from the planar surface of the thermal source is greater than a distance between the second surface of the retaining plate and the planar surface of the thermal source.

18. The support system of claim 17,
wherein the first retaining feature limits movement of the curved structure away from the planar surface of the thermal source, and
wherein contact between the flat bottom surface and the planar surface of the thermal source prevents rotation of the curved structure about any axis that is parallel to the planar surface of the thermal source.

19. A method comprising:
supporting a substrate on a support system, the support system comprising:
a thermal source;
a curved structure, wherein the curved structure has a curved supporting surface and a flat bottom surface, wherein the flat bottom surface faces a surface of the thermal source; and
a retaining plate including a first surface that rests on the surface of the thermal source, a second surface opposite to the first surface, and a retaining feature,
wherein the curved structure is positioned in the retaining feature and at least part of the curved supporting surface extends above the second surface of the retaining plate, and
wherein the retaining feature has a surface that limits movement of the curved structure away from the thermal source.

20. The method of claim 18, further comprising:
prior to supporting the substrate, performing a plurality of anteceding processing steps to the substrate to add one or more films to the substrate;
removing the substrate from the support system; and
additional processing the substrate to manufacture a plurality of articles.

21. The method of claim 20, wherein one of the plurality of a anteceding processing step is adding a planarization layer using inkjet adaptive planarization.
